(19) United States
(12) Patent Application Publication
(10) Pub. No.: US 2007/0077748 A1
(43) Pub. Date: Apr. 5, 2007

(54) Method for forming a semiconductor product and semiconductor product

(76) Inventors: Dominik Olligs, Dresden (DE); Hocine Boubekeur, Dresden (DE); Veronika Polei, Dresden (DE); Nicolas Nagel, Dresden (DE); Torsten Mueller, Dresden (DE); Lars Bach, Ullersdorf (DE); Thomas Mikolajick, Dresden (DE); Joachim Deppe, Dresden (DE)

Correspondence Address: SLATER & MATSIL LLP, 17950 PRESTON ROAD, SUITE 1000, DALLAS, TX, 75252, US

(21) Appl. No.: 11/241,877

(22) Filed: Sep. 30, 2005

(51) Int. Cl. H01L 21/4763; H01L 21/3205; H01L 21/44

(52) U.S. Cl. 438/618; 438/588; 438/673; 438/587; 438/597

(57) ABSTRACT

A semiconductor product (1) includes a plurality of wordlines extending along a first lateral direction (x) along a substrate surface (22) and also includes contact structures (3) as well as filling structures (4) therebetween. Along the first direction (x) the contact structures (3) and the filling structures (4) are arranged in alternating order between two respective wordlines. Each contact structure (3) serves to connect two active areas (23) separated by one respective trench isolation filling (24) to a respective bitline (14). Accordingly, the width of the first contact structures (3) is much larger than the width of the bitlines (14) along the first direction (x). According to embodiments of the invention, tapered upper portions (9) of the contact structures (3) are shaped, the upper portions (9) having a width being significantly smaller than the width of the contact structures (3) along the first direction (x). Thereby, forming the bitlines (14) in direct contact to top surfaces (7) of contact structures (3) is possible without the risk of short circuits between adjacent bitlines (14).

### TECHNICAL FIELD

The invention relates to a semiconductor product and to a method for forming a semiconductor product.

### BACKGROUND

Such a semiconductor product may be, for instance, a flash memory product comprising a plurality of memory cells like NROM (nitride read only memory) or alternative kinds of non-volatile memory cells (like floating gate cells). In a flash memory product, the memory cells are programmable individually selectively to the respective other memory cells. When information is deleted, all memory cells of the same particular sector are commonly deleted at the same time. The memory cells of the respective sector may be later reprogrammed individually.

The memory cells of a flash memory are arranged in a virtual ground array or in other array architectures. Each memory cell is connected to two respective bitlines running parallel to one another. In a virtual ground array each bitline is connected to memory cells arranged on opposed sides of the bitline. Connection between the bitlines and the memory cells is provided by contact structures that comprise first contacts called “local interconnect”. The local interconnects are arranged in rows extending perpendicular to the direction of the bitlines. In direction parallel to the bitlines, a bitline is connected to one respective local interconnect of every other row of local interconnects. Furthermore, in every other row, the local interconnects have a lateral offset relative to the lateral positions of the local interconnects of the other rows of local interconnects. Each bitline is connected to local interconnects of every other row (for instance of a first, third, fifth, etc., row) whereas the bitline is passing over memory cells of a second, fourth, sixth, etc., row of local interconnects without being connected to the local interconnects of the second, fourth and sixth rows.

In a virtual ground array, the bitlines are connected to the memory cells via contact structures that, according to prior art, comprise a first contact called “local interconnect”. The local interconnects are contact hole fillings provided in a dielectric layer above a substrate. The local interconnects are wide via contacts having a main extension in a first lateral direction perpendicular to the direction of the bitlines. They serve to connect two line-shaped active areas to a bitline. The active areas are doped regions providing the source/drain regions and the channel regions and, in a virtual ground array, are formed in lines or stripes separated from one another by trench isolation fillings like shallow trench isolations (STI). The trench isolation fillings as well as the active areas are formed line-shaped seen from top view on the semiconductor substrate. When the bitlines are formed, they are positioned such that they are running parallel to the active areas.

The local interconnects' contacts, in direction perpendicular to the active areas, extend beyond the bitlines on opposed sides of the respective bitline. In particular, the local interconnects extend to the active areas next to the bitline positioned on opposed sides of the bitline. Typically, a local interconnect has a width being approximately three times the width of the bitline since the width of the active areas and the width of the trench isolation fillings between the active areas correspond to one another.

In order to connect the bitline to the local interconnects, which are much wider than the bitlines, conventionally bitline contacts (the “contacts to interconnect”) are formed according to prior art. To this end, a dielectric layer is deposited and via contact holes are etched in the dielectric layer so as to expose a portion of an upper surface of the local interconnects. The contact holes in the second dielectric layer are then filled with conductive material. By planarizing the conductive material, the contacts to interconnect are formed. Subsequently, the bitlines are formed.

The wide local interconnects are required for contacting two respective areas. In the process of manufacturing the semiconductor product, a substrate is provided and a plurality of line-shaped active areas as well as a plurality of line-shaped trench isolation fillings disposed between respective two active areas are formed in the substrate. Subsequently a layer stack comprising a bottom oxide layer, a charge-trapping layer like a silicon nitride layer and a top oxide layer are deposited. Wordlines are then formed by depositing one or more conductive layers and a cap nitride layer for forming gate stacks. These layers are then pattered thereby forming a plurality of wordlines. Sidewall spacers are then formed on sidewalls of the wordlines in conventional manner.

Thereby a plurality of wordlines arranged at a distance from one another and running, at least in a region of the substrate surface, along a first direction, are provided. In spaces left between respective two wordlines the contact structures (the local interconnects) are to be formed thereafter. Thereby a semiconductor product is provided that comprises contact structures filled in vias, which vias are confined, on opposed sides along the first direction, by sidewalls of respective two portions of the filling structure (which portions have been separated from one another during trench etching). Along the second direction, the contact structures are confined by respective two wordlines (that is by their spacers).

Each contact structure formed in this way contacts two active areas arranged at a distance from one another along the first direction. Typically the width of the active area corresponds to the width of the trench isolation filling provided therebetween. The width of the contact structure in the first direction accordingly is approximately three times the width of an active area or of a trench isolation filling, along the first direction.

Accordingly, in a conventional semiconductor product second contact structures called “contact to interconnect” are provided between the first contact structures (the local interconnects) and the bitlines. Conventionally these second contact structures are required in order to connect the bitlines to the first contact structures. Since the first contact structures are contacting two active areas and, therefore, have a width typically corresponding to three times the critical dimension, in absence of the second contacts the bitlines would be short-circuited to one another in case that they would be provided directly on the first contact structures in a conventional semiconductor product.

In order to avoid short-circuiting, conventionally the second contact structures are provided therebetween. However, forming the second contact structures requires additional process steps thereby increasing the efforts and the costs of semiconductor product manufacture. Furthermore, when lithographically patterning masks for etching the second contact structures and the bitlines, there is a risk of lateral misalignments of the second contact structures relative to the first contact structures and, more critical, of the bitlines relative to the second contact structures. In case of lateral misalignments the contacts interface surfaces are reduced and the performance of the semiconductor product is decreased. Furthermore, etching through any dielectric layer arranged between the second contact structures has to be avoided during patterning of the bitlines. With view to these risks and drawbacks, conventionally connecting of the bitlines to the lower contact structures (the local interconnects) is critical with view to lateral misalignments and, due to the large width of the first contact structures, is more complicated and expensive as in case of connecting bitlines to other kinds of contact structures having a comparatively low lateral width.

### SUMMARY OF THE INVENTION

In one aspect, the present invention facilitates coupling the bitlines to the wide lower contact structures to decrease the efforts and costs of manufacturing the semiconductor products. In a further aspect, the invention reduces the risk of decreasing electrical conductivity and performance of the electrical connections formed of contact structures and bitlines in case of lateral misalignments. In one embodiment, for example, a semiconductor product and method of forming a semiconductor product are less expensive and less susceptible to the decrease of performance in case of lateral misalignments. Furthermore, the method of the invention and the semiconductor product of the invention shall be less complicated compared to prior art.

According to a first embodiment of the invention, a method for forming a semiconductor product includes the steps of:

a) providing a substrate having a substrate surface;

b) forming wordlines above the substrate, the wordlines extending along a first direction parallel to the substrate surface and being provided at a distance from one another;

c) forming contact structures and first filling structures between the wordlines, the contact structures having a lateral width along the first direction and being separated along the first direction by the first filling structures;

d) forming a mask, the mask comprising mask openings extending along a second direction parallel to the substrate surface, the second direction being different from the first direction;

e) wet etching portions of the contact structures through the mask openings, thereby reducing a width of upper portions of the contact structures along the first direction and forming recesses between the upper portions of the contact structures and the first filling structures;

f) filling the recesses with second filling structures; and

g) forming bitlines contacting the upper portions of the contact structures, the bitlines crossing over the contact structures along the second direction.

According to another embodiment of the invention a method for forming a semiconductor product is provided, which allows arranging the bitlines directly on the (lower) contact structures provided on the substrate surface. According to embodiments of the present invention, no second contact structures between the wide contact structures and the bitlines are required any longer. Whereas in conventional techniques using lithographic mask patterning and etching, the width of the contact structures is essentially uniform across the height of the contact structures in direction perpendicular to the substrate surface. It is an idea underlying embodiments of the present invention to shape the contact structures in such a way that the top surfaces of the contact structures have a width that is smaller than the width of the contact structures at their bottom arranged on the substrate surface.

According to another embodiment of the invention, after having formed the contact structures in step c), an additional mask is provided in step d) and step e) of etching, preferably wet etching of the contact structures is provided, thereby reducing the width of upper portions of the contact structures through openings of the mask. Between step c) and step d) the contact structures yet have a substantially uniform width along the first direction across their height. However, due to the provisions of step d) and e), recesses are etched into the contact structures by removing material of upper portions of the contact structures, thereby reducing the lateral width of the upper portions of the contact structures along the first lateral direction. Thereby the width of the top surface of the contact structures along the first direction is reduced so as to achieve a contact structure top surface having a substantially narrower width than the width of bottom surfaces of the contact structures. This technique then allows to directly connect the bitlines to the top surfaces of the contact structures without the risk of short circuits between bitlines adjacent to one another. Though the contact structures still are connecting two active areas, the wet etching of step e) is tapering the upper portions of the contact structures so as to provide contact structure top surfaces having substantially the same width as the bitlines to be connected thereto. In step f), the recesses formed by etching of contact structure material are filled with second filling structures and in step g) the bitlines are formed directly on the top surfaces of the contact structures, the bitlines contacting top surfaces of the contact structures and crossing over contact structures along a second direction different from (and preferably normal to) the first direction. The first and second filling structures are dielectric filling structures. They are filling any spaces and recesses between the tapered contact structures.

Preferably in step d) a mask is formed, which is covering first portions of top surfaces of the contact structures and which comprises mask openings exposing second portions of top surfaces of the contact structures. Accordingly, the mask is patterned such that first portions (of top surfaces having substantially the same width as the contact structures) are covered with the mask whereas second portions of these wide top surfaces are exposed by the mask openings. Accordingly, the exposed second portions of the initial top surfaces are removed by recessing so as to maintain a narrow top surface having a width being equal to or smaller than the width of the first portions of the initial top surface.

Preferably, forming the contact structures includes epitaxially growing a monocrystalline semiconductor material on the substrate, between the wordlines, and in step e) the monocrystalline semiconductor material is etched with an etching rate depending on crystallographic orientation of the local outer surface of the semiconductor material, thereby forming facets having predefined crystallographic orientations, which facets are confining the upper portions of the contact structures. According to this embodiment, selective etching with an etching rate depending on respective crystallographic orientations of local surface portions of the contact structures is applied in order to form large planar surface portions (facets) of predefined crystallographic orientation relative to the semiconductor material, these facets are confining the upper portions of the contact structures. The idea of this embodiment is to use the predefined crystallographic orientation of rapidly etched surfaces for providing inclined surfaces having predefined and constant angles of inclination with respect to the normal direction to the substrate surface. By using wet etching selective to crystallographic orientation, uniform adjustment of the width of the upper ends of the contact structures is achieved in case that all contact structures have substantially the same height.

Preferably step e) includes forming facets of predefined crystallographic orientation, thereby forming tapered upper portions of the contact structures, the tapered upper portions having top surfaces being smaller, along the first direction, than the width of the contact structures along the first direction. The upper surfaces each can abut to one or two inclined surfaces of the upper portions of the contact structures, for instance.

Preferably contact structures are formed of monocrystalline silicon. The monocrystalline silicon preferably is doped monocrystalline silicon.

According to an alternative embodiment, step e) includes isotropically underetching the upper portions of the contact structures through the mask openings. Also according to this technique the width of upper surfaces of the contact structure is decreased significantly, for instance to a width below the width of the first portions of the initial contact structure top surfaces covered with the mark in step b).

Preferably step c) includes:

depositing a conductive material between the wordlines;

patterning the conductive material thereby forming the contact structures; and

filling spaces between the contact structures with dielectric material and planarizing the dielectric material, thereby forming the first filling structures.

According to this embodiment conductive material for forming the contact structures is deposited and patterned first before filling spaces therebetween with dielectric material.

Alternatively, step c) includes:

depositing a dielectric material between the wordlines;

patterning the dielectric material thereby forming the first dielectric filling structures; and

depositing a conductive material between the first filling structures and planarizing the conductive material, thereby forming the contact structures.

According to this alternative embodiment, the dielectric material for forming the first filling structures is deposited and patterned first before depositing conductive material for the contact structures therebetween.

Preferably the second filling structures, which have been formed in step f), are planarized between steps f) and g). Thereby a plurality of separate second filling structures made of dielectric material is provided between the tapered upper portions of the contact structures and the first filling structures made of dielectric material.

Preferably in step d) a mask is formed that covers centered first portions of top surfaces of the contact structures, the centered first portions being arranged in centered positions along the first direction, and the mask comprises mask openings exposing second portions of the top surfaces of the contact structures, the second portions being arranged on opposed sides of the first portions along the first direction. According to this embodiment, symmetrically shaped contact structures are formed that comprise a top surface arranged in a centered position along the width of the contact structures in the first lateral direction. Accordingly two inclined surfaces are abutting to a top surface, the inclined surfaces being arranged on opposed sides of the top surface.

Alternatively, in step d) a mask is formed that comprises mask openings being asymmetrically arranged on the top surfaces of the contact structures, for each respective contact structure only one second portion of the top surface being exposed, the second portion being arranged in a decentered position along the first direction. The mask opening is at least extending to one of the lateral ends of the contact structure along the first direction.

Embodiments of the invention allow shaping the contact structures such that very narrow top regions (which preferably are uppermost regions of the upper portions of the contact structures) are formed, the top regions having a width significantly smaller than the width of the contact structures along the first direction. According to a preferred embodiment, such top regions of the tapered upper portions of the contact structures are removed when planarizing the second filling structures between steps f) and g). By adjusting the height above the substrate surface, in which height the second filling structures, the first filling structures and the contact structures are planarized, the width of the top surfaces of the contact structures along the first lateral direction is adjusted.

Accordingly in steps e) and f) the contact structures are shaped such that top surfaces of the contact structures have a width smaller than the width of the contact structures along the first direction.

Preferably step g) includes depositing a conductive material on top surfaces of the contact structures and patterning the conductive material, thereby forming the bitlines. The conductive material for forming the bitlines is a second conductive material, which may be the same conductive material as provided for the contact structures but which also may be a different conductive material. However, preferably a second conductive material is a metal or a metal alloy or polysilicon whereas the conductive material forming the contact structures may be a metal, a metal alloy, polysilicon or a polycrystalline or monocrystalline semiconductor material, the semiconductor material being doped in order to allow electrical contacting of the active areas to the bitlines.

In another embodiment, the invention relates to a method of forming a semiconductor product that includes the steps of:

a) providing a substrate having a substrate surface;

b) forming wordlines above the substrate, the wordlines extending along a first direction parallel to the substrate surface and being provided at a distance from one another;

c) forming contact structures between the wordlines, the contact structures having the width along the first direction and being separated along the first direction from one another by spaces;

d) wet etching the contact structures thereby forming tapered upper portions of the contact structures, the tapered upper portions each comprising top regions being smaller, along the first direction, than the width of the contact structures along the first direction;

e) filling the spaces between the contact structures and covering the tapered upper portions of the contact structures with a dielectric material;

f) planarizing the dielectric material; and

g) forming bitlines contacting the top regions of the upper portions of the contact structures.

According to this alternative method, no dielectric filling structures are provided between the contact structures prior to wet etching the contact structures for forming the tapered upper portions thereof. Instead, spaces between the contact structures are exposed and wet etching is applied both to the top surfaces and to the sidewalls of the contact structures. Since at edges between the top surfaces and the sidewalls of the contact structures any etching component rapidly etching from two directions, the edges are etched more than lower sidewall regions or centered regions of the top surfaces of the contact structures.

Preferably the contact structures are formed of a monocrystalline semiconductor material epitaxially grown on the substrate surface in step c) and in step d) the contact structures are etched with an etching rate depending on the crystallographic orientation of the local outer surface of the monocrystalline semiconductor material, thereby forming facets of predefined crystallographic orientation being inclined relative to the substrate surface, the facets confining the tapered upper portions of the contact structures. According to this preferred embodiment the contact structures are formed of monocrystalline semiconductor material. Accordingly, wet etching mainly occurs along those directions corresponding to predefined crystallographic orientations of the monocrystalline substrate material. Though selective etching does not exclude that the semiconductor material is also etched along further directions that correspond to other predefined crystallographic orientations or that do not correspond to any common crystallographic orientation, it is an advantage of selective etching that along some predefined crystallographic orientations the etching rate is rather high compared to the etching rate along other crystallographic orientations or along directions that do not correspond to a common crystallographic orientation. For instance, the semiconductor material of the contact structure may be etched with a maximum etching rate in direction along 45° with respect to the substrate surface, thereby forming inclined surfaces very precisely shaping the profile of upper portions of the contact structures. Since the predominant etching rate along this direction is the largest compared to etching rates along other directions, during wet etching the cross-section and diameter of the etched facets orientated at an angle of 45° with respect to the substrate surface increases.

Preferably the contact structures are formed of monocrystalline silicon, which preferably is doped silicon.

Preferably, in step d) tapered upper portions comprising centered top regions are formed, the centered top regions being arranged in centered positions along the first direction, and step f) includes removing the centered top regions of the tapered upper portions. According to this embodiment, symmetrically shaped contact structures are formed suitable for providing the bitlines in centered positions directly on the contact structures. Alternatively, asymmetrically shaped contact structures may be formed, which allow formation of the bitlines in de-centered positions with regard to the first lateral direction.

Alternatively, step f) includes exposing top surfaces of the tapered upper portions of the contact structures, the exposed top surfaces being parallel to the substrate surface and having a width, along the first direction, being smaller than the width of the contact structures along the first direction.

Alternatively, in another embodiment, the invention provides a method of forming a semiconductor product that includes the steps of:

a) providing a substrate having a substrate surface;

b) forming wordlines above the substrate, the wordlines extending along a first direction parallel to the substrate surface and being provided at a distance from one another;

c) depositing a conductive material between the wordlines;

d) forming a mask on the wordlines and on the conductive material, the mask, comprising mask openings extending along a second direction parallel to the substrate surface, the second direction being different from the first direction;

e) etching the conductive material through the mask openings, thereby forming contact structures having a width along the first direction and being separated from one another along the first direction by spaces, the contact structures comprising sidewalls being inclined relative to the substrate surface and further comprising upper portions that have a width, along the first direction, smaller than the width of the contact structures along the first direction;

f) filling the spaces between the contact structures with a dielectric material; and

g) forming bitlines contacting the upper portions of the contact structures, the bitlines crossing over the contact structures along the first direction.

According to this method a conductive material deposited between the wordlines is etched such that a plurality of contact structures comprising inclined surfaces being inclined relative to the normal to the substrate surface are formed, thereby yielding trapezoidal shapes of the contact structures. Accordingly, a significant slope of the sidewall surfaces relative to the normal to the substrate surface exists, thereby shaping contact structures, which on each opposed side have an additional width of at least half of the critical dimension at their bottom side compared to the width at their top side.

Preferably in step e) contact structures comprising sidewalls inclined by an angle of larger than 10° relative to the normal direction to the substrate surface are formed. More preferably, in step e) contact structures comprising sidewalls inclined by an angle of between 10° and 45°, preferably of between 15° and 25° relative to the normal direction to the substrate surface are formed.

Preferably the dielectric material is planarized between steps f) and g).

Anyone of the above methods according to the invention and their embodiments may be applied to form flash memories, thereby resulting in further embodiments described herein below. Preferably, for instance, step a) includes providing a substrate comprising active areas formed line-shaped and extending along a second direction different from the first direction, the substrate further comprising trenches arranged between the active areas and filled with trench isolation fillings, each trench isolation filling being formed line-shaped and isolating to respective active areas from one another.

Furthermore, preferably the contact structures each contacting two respective active areas and passing across one respective trench isolation filling are formed.

According to a preferred embodiment of NROM devices, for instance, in step a) a substrate is provided, which further comprises a charge-trapping layer sandwiched between a top oxide layer and a bottom oxide layer, the bottom oxide layer being disposed on the substrate surface. Preferably in step b) the wordlines are formed on the top oxide layer. The charge trapping layer preferably is a silicon nitride layer.

Preferably contact structures are formed, which are arranged at a distance from one another, along the first direction, which distance corresponds to the width of the trench isolation fillings along the first direction. Accordingly, the contact structures are separated by spaces having approximately the same width as the trench isolation fillings. However, the contact structures are formed above the substrate whereas the trench isolation fillings are arranged in the substrate.

In another aspect, embodiments of the present invention provide a semiconductor product that includes:

a substrate having a substrate surface;

a plurality of wordlines arranged at a distance from one another and running along a first direction over the substrate surface;

a plurality of contact structures provided between the wordlines and a plurality dielectric filling structures provided between the wordlines, the filling structures separating the contact structures from one another along the first direction, the contact structures contacting the substrate surface and comprising a top surface provided at a distance from the substrate surface, the contact structures further having a width along the first direction; and

a plurality of bitlines contacting the top surfaces of the contact structures,

wherein the contact structures each are formed of an integrally formed conductive structural element comprising inclined surfaces;

wherein the contact structures each comprise a lower portion and an upper portion;

wherein the top surface forms part of the upper portion of the respective contact structure; and

wherein the upper portions of the contact structures each comprise an inclined surface being inclined relative to the substrate surface and relative to the normal direction to the substrate surface, the top surface abutting to the inclined surfaces and having a width along the first direction being smaller than a width of the contact structure along the first direction.

Accordingly, a semiconductor product is provided that comprises a plurality of integrally formed contact structures which, in contrast to prior art, do not comprise a first and a second structural element (like the local interconnect and the contact to interconnect) but that only comprise one integral piece of conductive material arranged on the substrate surface. This piece of conductive material serves as a local interconnect for contacting the substrate surface but is shaped such that its upper portion comprises inclined surfaces and a top surface having a width significantly smaller than the width of the contact structure along the first direction. Accordingly, the width of the top surface of the contact structure is small enough to allow direct arrangement of the bitlines thereon without any risk of causing short circuits to other, adjacent bitlines.

According to a preferred embodiment the contact structures are formed of a monocrystalline silicon material and the inclined surfaces are facets having a predefined crystallographic orientation relative to the monocrystalline semiconductor material. Accordingly, a contact structure with inclined surfaces of precisely determined orientations relative to the normal to the substrate surface is provided, which facilitates adjusting the width of the top surface that simply depends on the total vertical extension of the contact structures.

Preferably, the lower portions of the contact structures comprise sidewalls arranged at a distance from one another larger than the width of the top surface along the first direction. Accordingly, the sidewalls of lower portions are substantially parallel to one another and perpendicular to the substrate surface.

Preferably, the lower portions of the contact structures comprise sidewalls arranged at a distance from one another corresponding to the width of the contact structures along the first direction.

According to one embodiment, the top surfaces of the contact structures are arranged in a centered position, along the first direction, on the upper portions of the contact structures. The top surfaces form part of the upper portions of the contact structures. According to this embodiment, they are symmetrically arranged between both ends of the contact structures in the first direction.

Accordingly, each contact structure comprises two respective inclined surfaces arranged on opposed sides of the centered top surface.

Alternatively, each contact structure may comprise a tapered upper portion comprising only one inclined surface and one top surface parallel to the substrate surface. In this case the top surface is abutting to one sidewall and to the one inclined surface. However, two or more inclined surfaces may be provided.

Preferably, the sidewalls and the inclined surfaces of the contact structures are abutting to dielectric filling structures. For instance, the sidewalls of the lower portions may abut to first filling structures wherein the inclined surfaces of the upper portions are abutting to second filling structures. The first filling structures preferably filling spaces between the patterned contact structures whereas the second filling structures are filling recesses etched when forming the tapered upper portions.

Preferably, the width of the top surfaces of the contact structures along the first direction is less than two thirds, preferably less than half of the width of the contact structures along the first direction.

According to the above and subsequent embodiments of the semiconductor product, the contact structures comprise upper portions that are integrally formed with the lower portions, the upper and lower portions forming one integrally formed structural element formed by deposition of conductive bulk material by only one single deposition step. Accordingly, there is no interface surface between the lower portions and the upper portions.

In another embodiment, the invention provides by a semiconductor product that includes:

a substrate having a substrate surface;

a plurality of wordlines arranged at a distance from one another and running along a first direction over the substrate surface;

a plurality of contact structures provided between the wordlines and a plurality of dielectric filling structures provided between the wordlines, the filling structures separating the contact structures from one another along the first direction, the contact structures contacting the substrate surface and comprising a top surface provided at a distance from the substrate surface, the contact structures further having a width along the first direction; and

a plurality of bitlines contacting the top surfaces of the contact structures,

wherein the contact structures each are formed of an integrally formed conductive structural element comprising inclined surfaces; and

wherein the contact structures comprise inclined surfaces extending from the substrate surface to the top surface of the contact structure, the inclined surfaces being inclined by an angle of larger than 10° relative to the normal direction to the substrate surface.

According to this embodiment, contact structures are formed that have inclined sidewalls having a considerable slope compared to the normal direction to the substrate surface, the slope being at least 10° in order to contact the complete surface width of at least two active areas.

Preferably, the inclined surfaces are inclined by an angle of between 10° and 45°, preferably of between 15° and 25° relative to the normal direction to the substrate surface.

Preferably, each contact structure comprises two inclined surfaces abutting to the top surface and being arranged on opposed sides of the top surface.

Preferably, the width of the top surfaces of the contact structures along the first direction is less than two-thirds, preferably less than half of the width of the contact structures along the first direction.

Preferably, the substrate comprises active areas, the active areas being formed line-shaped and extending along a second direction different from the first direction.

Preferably, the substrate comprises trenches arranged between the active areas and being filled with trench isolation fillings, each trench isolation filling being formed line-shaped and isolating two respective active areas from one another.

Preferably, each contact structure contacts two respective active areas and is passing across one respective trench isolation filling.

Preferably, the semiconductor product comprises portions of a charge-trapping layer arranged between the active areas and the wordlines.

Preferably, each portion of the charge-trapping layer is sandwiched between a bottom oxide layer and a top oxide layer.

Preferably, the charge-trapping layer is a silicon nitride layer.

Preferably, the semiconductor product comprises a memory array comprising a plurality of non-volatile memory cells. Thereby flash memory semiconductor products are provided that comprise integrally formed local interconnect contact structures allowing direct contact to the bitlines provided thereon.

Hereinbelow the invention is described with reference to the figures.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a top view of a semiconductor product according to one embodiment of the invention;

FIGS. 2 to 11 illustrate a first method according to one embodiment of the invention for forming a semiconductor product;

FIGS. 12 to 14 illustrate a second method according to an embodiment of the invention for forming a semiconductor product;

FIGS. 15 to 18 illustrate a third method according to an embodiment of the invention for forming a semiconductor product; and

FIGS. 19 to 22 illustrate a fourth method according to an embodiment of the invention for forming a semiconductor product.

The following list of reference symbols can be used in conjunction with the figures:

| | |
|---|---|
| 1 | Semiconductor product |
| 2 | Substrate |
| 3 | Contact structure |
| 3a | Sidewall |
| 4 | First filling structure |
| 5 | Second filling structure |
| 6 | Lower portion |
| 7 | Top surface |
| 8 | Monocrystalline semiconductor material |
| 9 | Upper portion |
| 10 | Wordline |
| 11 | Mask |
| 12 | Mask opening |
| 14 | Bitline |
| 15; 25 | Conductive material |
| 16 | Facet |
| 17 | First portion of top surface |
| 18 | Second portion of top surface |
| 19 | Inclined surface |
| 21 | Dielectric material |
| 22 | Substrate surface |
| 23 | Active area |
| 24 | Trench isolation filling |
| 25 | Bottom oxide layer |
| 26 | Charge-trapping layer |
| 27 | Top oxide layer |
| 28 | Trench |
| 29 | Top region |
| 31 | First layer |
| 32 | Second layer |
| 33 | Third layer |
| 34 | Wordline spacer |
| d | Width of upper portion |
| d1 | Distance |
| D | Width of contact structure |
| o | Crystallographic orientation |
| x | First direction |
| y | Second direction |
| z | Vertical direction |

### DETAILED DESCRIPTION OF ILLUSTRATIVE EMBODIMENTS

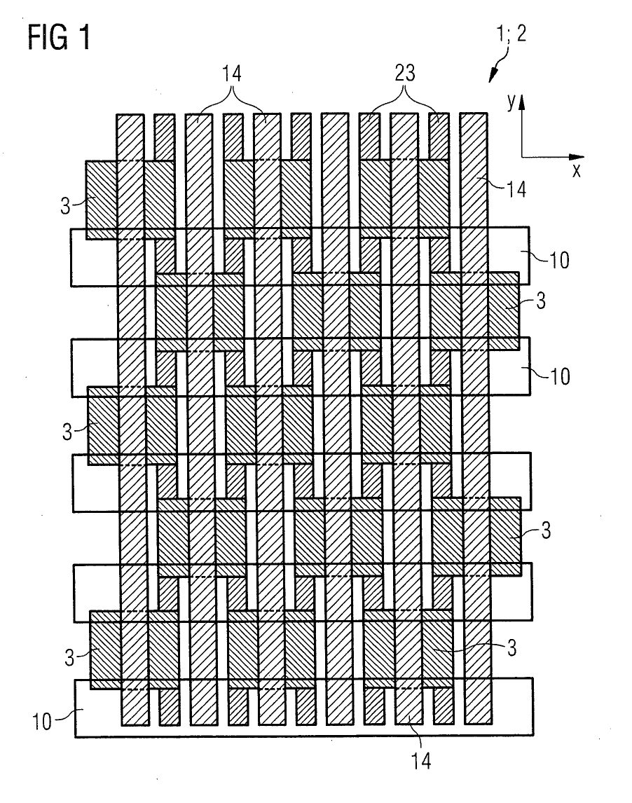

FIG. 1 illustrates a top view of a semiconductor product 1, in particular of a flash memory product comprising a plurality of memory cells arranged in a virtual ground array. In a substrate 2 a plurality of line-shaped active areas 23 are formed by implanting a dopant in the substrate 2. The substrate further comprises line-shaped trench isolation fillings. In FIG. 1 the trench isolation fillings are not visible since they are provided at the same lateral positions as the bitlines 28. Each line-shaped active area 23 is arranged between two respective line-shaped trench isolation fillings.

For clarity of illustration, in FIG. 1 the active areas 23 are designed narrower than the bitlines. In an actual semiconductor product, however, the active areas 23 have approximately the same width along the first direction x as the bitlines 14 or as the trench isolation fillings provided between the active areas 23.

FIG. 1 further illustrates wordlines 10 arranged at a distance from one another along a second direction y and extending along the first direction x. FIG. 1 further illustrates contact structures 3 each arranged between two respective wordlines 10 and each contacting two respective line-shaped active areas 23. On the contact structures 3, bitlines 14 are provided. Each bitline 14 is connected to a plurality of contact structures 3.

On a surface of the substrate 2 a charge-trapping layer is provided. The charge-trapping layer may be a silicon nitride layer contained in an ONO layer stack (oxide-nitride-oxide). The ONO layer stack may be present, for instance, all over the substrate surface except for those regions of the substrate surface where the contact structures 3 are provided. In this case, the formation of the contact structures 3 includes etching through the ONO layer stack. Alternatively, prior to formation of the contact structures 3, the ONO layer stack may be present on the active areas exclusively, for instance, and may be absent on the trench insulating fillings. In any case, the contact structures 3 are in contact with the substrate surface and each contact structure 3 contacts two line-shaped active areas 23. Since a nitride layer of the ONO stack is usable as a charge-trapping layer for storing electrical charges in locally bound positions, preferably an NROM memory product is provided, those portions of the line-shaped active areas 23 being covered with the contact structures 3 forming source/drain electrodes. The contact structures 3 are arranged in rows along the first lateral direction x. When comparing the contact structures 3 of two adjacent rows, the contact structures 3 have a lateral offset in direction x with respect to one another. The contact structures 3 are provided in spaces between the wordlines 10. The wordlines 10 have been formed prior to forming the contact structures 3.

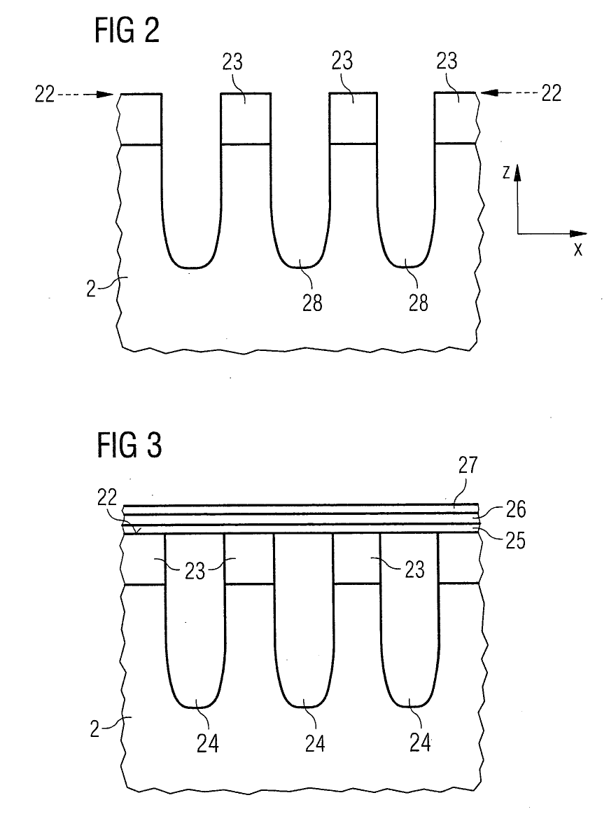

FIGS. 2 to 11 illustrate method steps of a first embodiment method according to the invention for forming a semiconductor product.

According to FIG. 2, a semiconductor substrate 2 is provided, the substrate 2 having a substrate surface 22. The substrate further comprises active areas 23 formed by implantation of a dopant into the substrate 2. The substrate further comprises trenches 28 formed line-shaped, having their main extension in direction perpendicular to the drawing plane. The trenches 28 have been etched into the substrate preferably after implanting the dopant for forming the active areas 23. Thereby line-shaped active areas 23 are formed, each line-shaped active area 23 being confined in the first direction x by two adjacent line-shaped trenches 28.

The trenches 28 are then filled with trench isolation fillings 24 (FIG. 3). The trench isolation fillings 24 comprise a dielectric material. Filling the trenches 28 with the trench isolation filling 24 may be performed by depositing a dielectric material into the trenches 28 and on top of the substrate surface 22 and subsequently removing (for instance, by polishing) the dielectric material from the substrate surface 22.

As illustrated in FIG. 3, on the substrate surface 22 a layer stack is formed by depositing a bottom oxide layer 25, a charge-trapping layer 26 and a top oxide layer 27 on one another. The bottom oxide layer 25 is deposited on the substrate surface 22 and covers the active areas 23 and the trench isolation fillings 24. The charge-trapping layer 26 preferably is formed of silicon nitride and serves for storing electrical charges in locally bound positions.

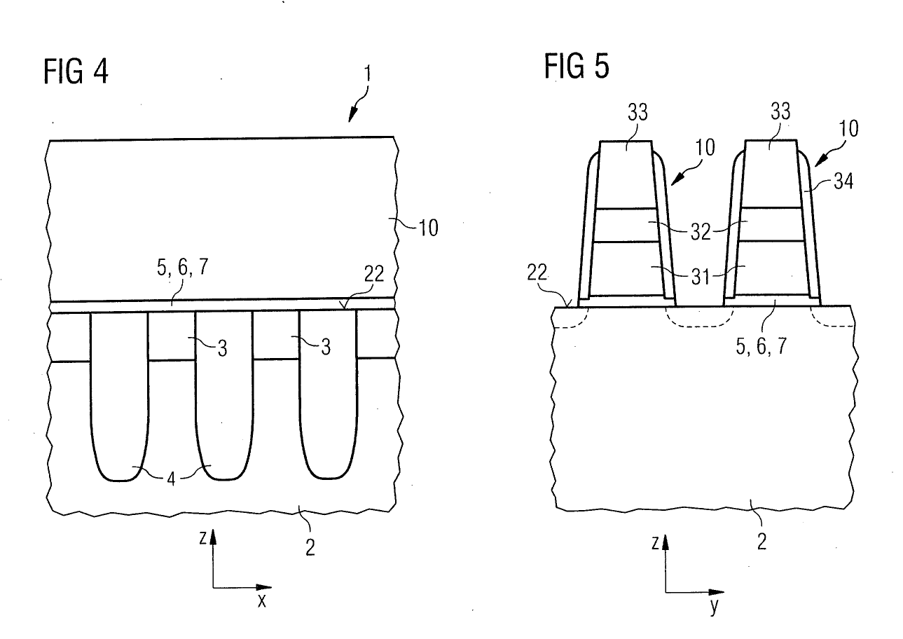

FIGS. 4 and 5 illustrate two cross-sectional views of the semiconductor product after formation of wordlines. FIG. 4 illustrates a cross-sectional view parallel to the wordlines and FIG. 5 illustrates a cross-sectional view perpendicular to the wordlines. According to FIG. 4, a wordline 10 extending along the first direction x is formed on the layer stack of the bottom oxide layer 25, the charge-trapping layer 26 and the top oxide layer 27. In FIG. 5 the cross-sectional shape of the wordlines 10 as well as the vertical structure of the wordlines is illustrated. The wordlines 10 may comprise a first layer 31, a second layer 32 and a third layer 33, for instance. The first layer 31 may be a polysilicon layer and the second layer 32 may be a conductive layer having an electrical conductivity higher than the conductivity of the polysilicon layer. The second layer 32 may comprise Tungsten. For instance, the second layer 32 may be a Tungsten silicide layer. The third layer 33 may be a nitride cap layer protecting the first layer 31 and the second layer 32 during patterning of the wordlines. The wordlines are formed by depositing the first, second and third layers 31, 32 and 33 on one another and patterning them subsequently, patterning being finished in the bottom oxide layer 25, for instance. An optional additional step of shaping the cross-sectional wordline profile may be performed in order to achieve a slope of the wordline sidewalls. Thereby tapered wordlines having a width along a second (lateral) direction y, which decreases with increasing distance from the substrate surface are formed. Accordingly, the first layer 31 of the wordlines 10 is wider than the third layer 33 thereof. The slope of the wordline sidewalls may be between 2° and 8° relative to the normal to the substrate surface, for instance about 5°. After having patterned the first, second and third layers 31, 32, 33 of the wordlines 10, LDD implants (lightly doped drain), for instance, may be implanted through the stack of layers 25, 26 and 27 into those regions of the substrate surface disposed between respective two adjacent wordlines 10.

FIGS. 4 and 5 each illustrate a cross-sectional view of a portion of a memory array of the memory product 1. The memory array is illustrated in FIG. 1 in top view.

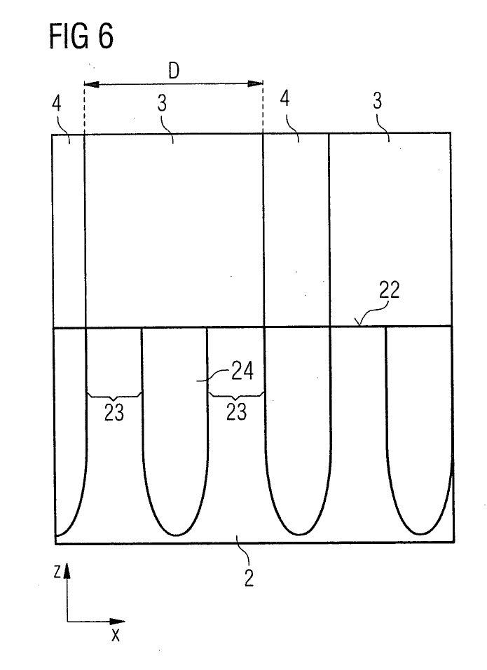

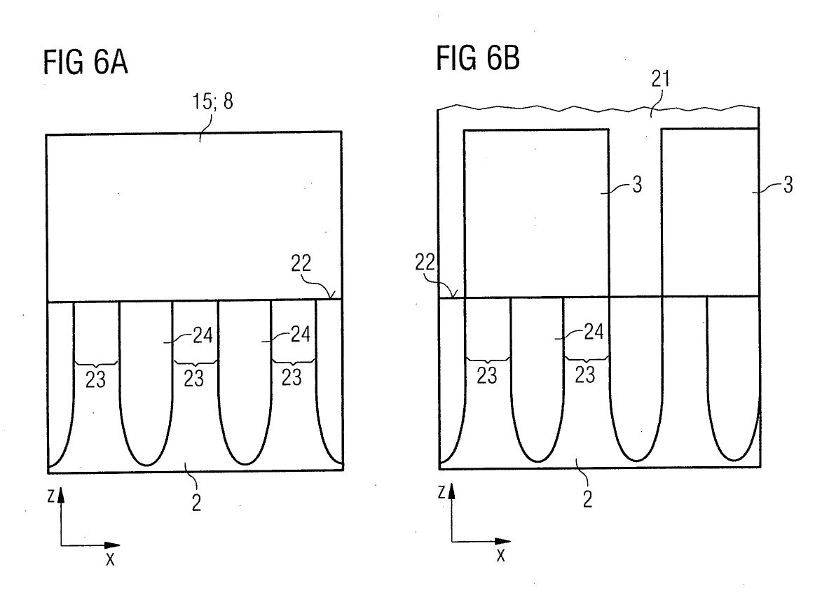

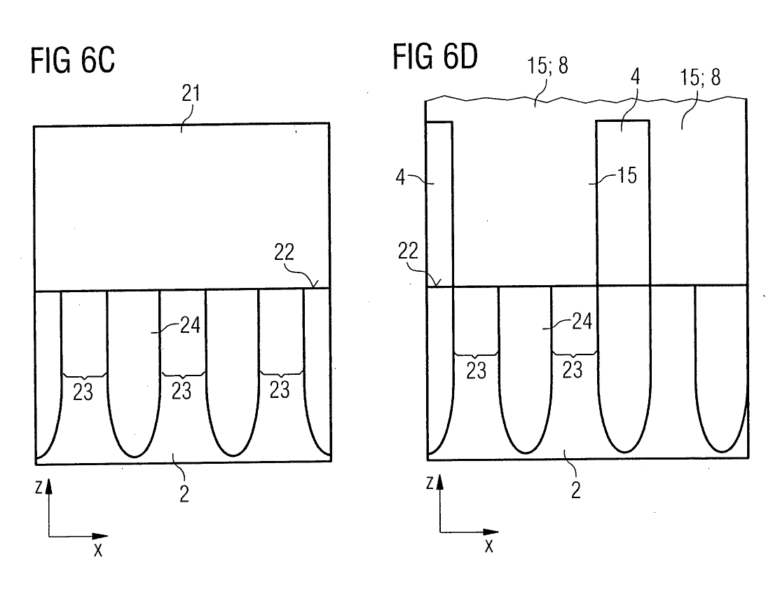

The method of this embodiment of the invention proceeds with forming contact structures and first filling structures as illustrated in FIG. 6. The contact structures 3 and the first filling structures 4 are provided between the wordlines and are arranged in alternating order along the first direction x. In FIG. 6 and the subsequent figures the ONO layer stack comprising the top oxide layer, the charge-trapping layer and the bottom oxide layer are not illustrated since the contact structures 3 are contacting the substrate surface 22. The step c) of forming the contact structures 3 and the first filling structures 4 may be performed by forming the dielectric filling structures after the contact structures (as illustrated in FIGS. 6A and 6B) or, alternatively, by forming the contact structures subsequent to forming the filling structures (as illustrated in FIGS. 6C and 6D). According to FIG. 6A, a conductive material 15 is deposited on the substrate surface 22 and is patterned so as to result in contact structures 3 illustrated in FIG. 6B. Subsequently, a dielectric material 21 is deposited on and between the contact structures 3. Upon removing any dielectric material 21 deposited on the contact structures 3, the arrangement of FIG. 6 is achieved, the arrangement providing contact structures 3 and first filling structures 4 interposed therebetween. According to FIG. 6 the contact structures 3 anywhere across their height have a substantially uniform width D being large enough to contact, on the bottom side of each contact structure, two respective active areas 23 and passing over a one respective trench isolation filling 24. Alternatively, the arrangement of FIG. 6 may be formed by first depositing a dielectric material 21 as illustrated in FIG. 6C and patterning the dielectric material 21 so as to form first dielectric filling structures 4 illustrated in FIG. 6D. Subsequently, a conductive material 15 is deposited on and between the first filling structures 4 (FIG. 6D). Upon planarizing any conductive material 15 arranged in a height above the first filling structures 4, the arrangement of FIG. 6 is achieved.

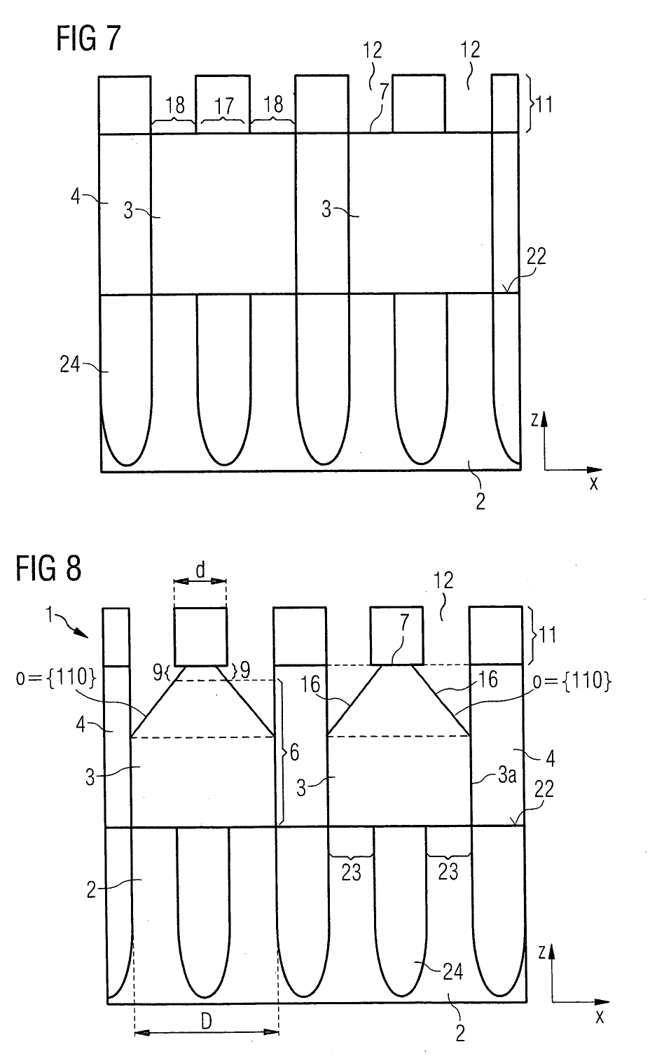

The method then proceeds with forming a mask 11 on the intermediate semiconductor product as illustrated in FIG. 7. The mask comprises mask openings 12 being line-shaped and extending along a direction perpendicular to the drawing plane, that is along a direction perpendicular to the first direction x. Accordingly, the mask portions and the mask openings 12 are crossing over the wordlines and over the contact structures 3 and the first filling structures 4.

The mask comprises mask portions that may, for instance, cover the first filling structures 4 and centered first portions 17 of the top surfaces 7 of the contact structures 3. In this case symmetrically shaped contact structures 3 are formed in the subsequent steps.

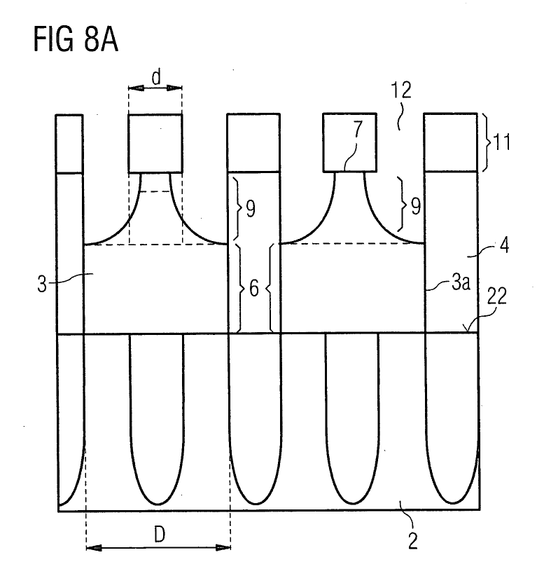

According to FIG. 8, the contact structures 3 are etched through the mask openings 12, preferably by wet etching. By means of etching through the mask openings 12 the width d of upper portions 9 of the contact structures 3 is reduced compared to the initial width D of the complete contact structures 3. In particular, the width of a top surface 7 of the upper portions 9 is reduced to a width being equal to or less than the width of mask portions between the mask openings 12.

According to FIG. 8, wet etching is performed with an etching rate depending on respective crystallographic orientations of the local outer surface of the contact structures 3. For instance, the etching rate may be rather high in direction of crystallographic planes corresponding to the Miller indices {110}, the sidewalls 3a of the contact structures 3 for instance having a direction of {100}. Accordingly, etching rate in diagonal direction with respect to the substrate surface 22 and its normal direction is performed rather rapidly, thereby shaping inclined facets 16 oriented at an inclination angle of 45° relative to the substrate surface 22. Though about a third of the width of the initial top surface 7 of the contact structures 3 (FIG. 7) is exposed by the mask openings 12, selective wet etching with increased etching rate along the crystallographic orientation {110} causes formation of inclined facets 16 confining the upper regions 9 (or the upper regions as well as portions of the lower regions 6) of the contact structures. Furthermore, two respective facets 16 are abutting to the top surface 7 in FIG. 8. Accordingly, the width d of the upper portions 9 and of the top surfaces 7 of the contact structures is reduced significantly compared to the initial width D of the contact structures 3.

FIG. 8A illustrates an alternative embodiment in which no facets of predefined crystallographic orientation are formed. Instead, rounded etching profiles are achieved. As in FIG. 8, the upper portions 9 of the contact structures 3 have a width being reduced compared to the initial width D of the contact structures 3 whereas lower portions 6 of the contact structures 3 maintain their original width D. Sidewalls 3a, as in FIG. 8, are substantially perpendicular to substrate surface and are arranged at a distance d1 from one another, which distance corresponds to the width D of the contact structures 3. The top surfaces 7 of the upper portions 9 of the contact structures however have a width d being equal to or smaller than the width of those portions 17 (FIG. 7) of the initial top surface 7 of the contact structure 3, which were covered with the mask portions of the mask 11.

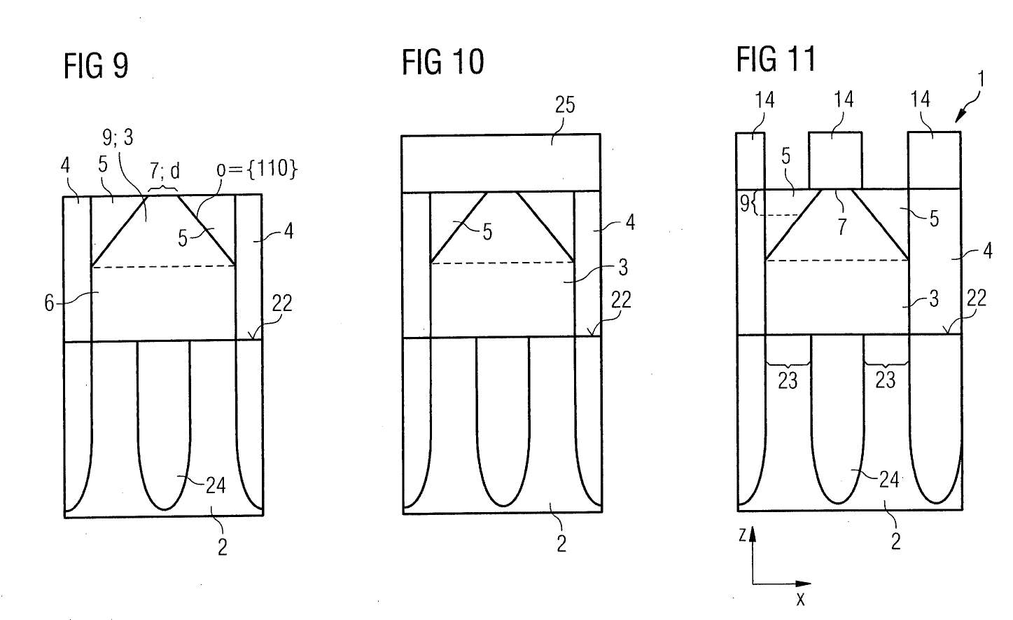

Subsequent to etching recesses into the conductive material of the contact structures 3 according to FIG. 8 or FIG. 8A, according to FIG. 9 second dielectric filling structures 5 are formed in order to fill the etched recesses in the upper portions 9 of the contact structures 3 with dielectric material. In case that the inclined surfaces confining the recesses are facets of predefined crystallographic orientation, the interface surfaces between the upper portions 9 and the second filling structures 5 are planar surfaces. In this case planarizing of the top surfaces of the intermediate semiconductor product may be used to easily adjust the desired width d of the top surface 7 of the upper portion 9 of the contact structures 3. Due to the predefined inclination angle of the planar inclined surfaces, the width d of the top surfaces is uniform, in a particular height about the substrate surface, for all contact structures 3 of the semiconductor product. However, also in case that the recesses have been formed by isotropical underetching according to FIG. 8A, the recesses are filled with second filling structures 5 corresponding to FIG. 9. In both cases the method then proceeds with depositing a conductive material 25 according to FIG. 10, wherein the conductive material 25 may be the same material as used for the contact structures 3 or, alternatively, may be another conductive material.

In the embodiment of FIG. 8 according to which facets having predefined crystallographic orientations are to be formed, the contact structures 3 must be formed of a conductive monocrystalline semiconductor material 8 to be deposited in FIGS. 6A or 6B. In particular, the monocrystalline semiconductor material 8 may be doped monocrystalline silicon epitaxially grown on the substrate surface 22. Alternatively, especially in case that isotropical underetching or another technique of forming the recesses in the upper portions 9 of the contact structures 3 is chosen, the material of the contact structures 3 may further be polysilicon or a metal or a metal alloy.

The conductive material 25 deposited according to FIG. 10 may be one of these further materials. According to embodiments of the invention a method then proceeds with FIG. 11 according to which bitlines 14 are formed of the conductive material 25. According to embodiments of the invention the bitlines 14 are formed directly on the top surfaces 7 of the contact structures 3. Since, according to embodiments of the invention, the width d of upper portions 9 of the contact structures 3 has been reduced significantly below the initial width D of the contact structures, no second contact structures need to be formed on the contact structures 3. Instead, the bitlines 14 are abutting to the top surfaces 7 of the contact structures 3 and the contact structures 3 are formed of an integrally formed structural element deposited by only a single method step (according to FIG. 6A or 6D). Accordingly, no conventional problem of adjusting the bitlines to second contact structures (the contacts to interconnect) occurs any longer. As illustrated in FIG. 11, the bitlines 14 are contacting the top surfaces 7 of the contact structures 3 and the bottom surfaces of the contact structures 3 are contacting two respective active areas 23 provided in the substrate and separated from one another by one respective trench isolation filling 24. Thereby the semiconductor product illustrated in FIG. 1 is formed and no risk of short circuits between the bitlines occurs. According to embodiments of the invention, there is no need to form second contact structures between the contact structures 3 and bitlines 14 for preventing such short circuits.

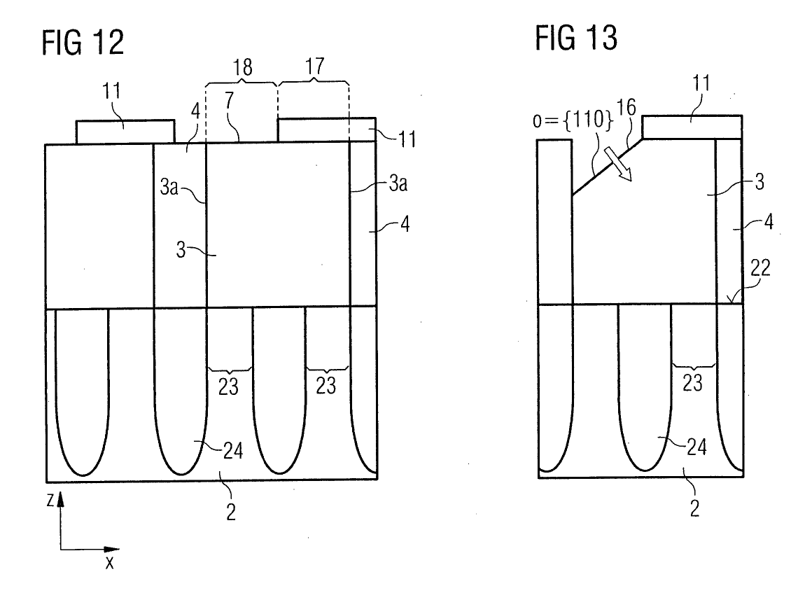

FIGS. 12 to 14 illustrate an alternative, second embodiment method according to an embodiment of the invention. In the alternative method, asymmetrically shaped contact structures are formed. The alternative method starts, as the method described above, with the steps of FIGS. 2 to 6. Subsequent to FIG. 6, a mask 11 is provided which, in contrast to the mask of FIG. 7, includes mask portions being asymmetrically arranged on the upper surfaces 7 of the contract structures 3. According to FIG. 12, the mask 11 is covering first portions 17 of the upper surfaces 7 of the contact structures 3, which first portions 17 are arranged in a decentered position along the first direction x with regard to the center of the contact structures 3. The first portions 17 extend to one sidewall 3a of the contact structures 3. The mask openings 12 expose second portions 18 of the top surfaces 7 of the contact structures 3, the second portions 18 also being arranged asymmetrically on the contact structures 3 and extending to the other sidewall 3a of the respective contact structure 3. Each mask opening 12 may partially expose the top surface 7 of one contact structure 3 and a portion of the top surface of one first dielectric filling structure 4.

According to FIG. 13, recesses are etched into the material of the contact structures 3 through the mask openings 12. As described with reference to FIGS. 8 and 8A, etching the recesses may be performed by wet etching with an etching rate depending on the local orientation of the outer surface of the contact structure material. Since for etching of planar facets 16 the material of the contact structure should be monocrystalline material, like a monocrystalline doped semiconductor material that is deposited epitaxially, there are predefined crystallographic orientations of the crystal lattice of contact structure material. For instance, the material of the contact structures may be grown on the substrate 2 such that the crystallographic orientation indicated by the group of Miller indices {100} are corresponding to the substrate surface 22 and to the normal direction z normal to the substrate surface 22. The direction in which the etching rate is rather high compared to other directions may be, for instance, the direction characterized by the group of Miller indices {110} that indicates inclined surfaces having an inclination angle of 45° relative to the substrate surface 22. In case that along these diagonal directions the etching rate during recessing of the contact structures is rather thigh, inclined facets 16 as illustrated in FIG. 13 (or FIGS. 8 and 9) will grow during progress of recess etching until the inclined facets 16 are abutting to the top surface of the contact structures and to the sidewalls thereof.

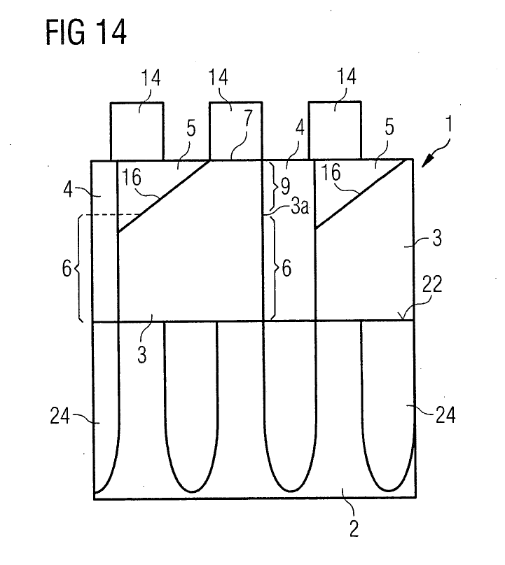

Etching of recesses into the contact structures 3 according to FIG. 13 may also be performed by means of isotropical underetching similarly as illustrated in FIG. 8A. After having formed recesses between the contact structures 3 and the first dielectric filling structures 4, the recesses are filled with dielectric material to form second dielectric filling structures 5 as illustrated in FIG. 14. Subsequently, the bitlines 14 are formed such that they are abutting to the top surfaces 7 of the contact structures 3. Since, according to the embodiment of FIGS. 12 to 14 the contact structures 3 are shaped asymmetrically, their top surfaces 7 and the bitlines 14 are arranged close to one sidewall 3a of each respective contact structure 3.

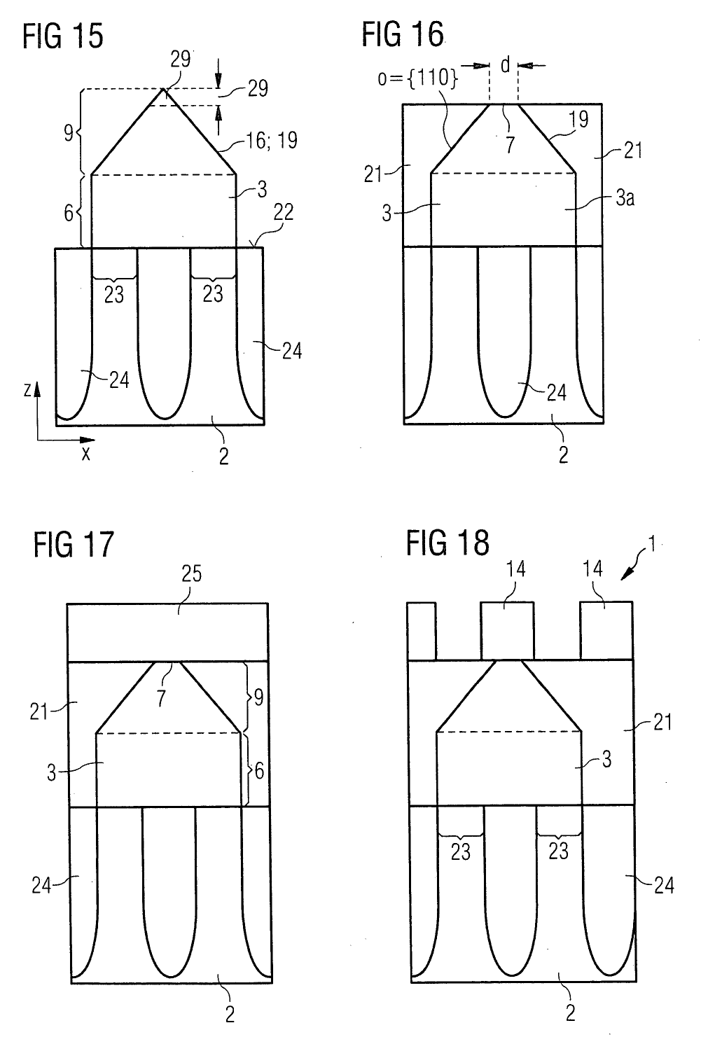

FIGS. 15 to 18 illustrate a third method for forming a semiconductor product according to embodiments of the invention. The method starts with the steps illustrated in FIGS. 2 to 5 and then proceeds with forming contact structures by depositing a conductive material 15 as illustrated in FIG. 6A and patterning the conductive material so as to obtain contact structures 3 as shaped in FIG. 6B. However, no dielectric material is deposited at this stage of the method and no dielectric filling structures are formed. Instead, the isolated, exposed contact structures 3 are etched by exposing them to an etching medium like an etching plasma or a wet etching medium. Thereby, the contour of the contact structures 3 is shaped so as to obtain tapered upper portions 9 of the contact structures 3 (FIG. 15). Since the etching component at the edges between the sidewalls and the top surface of the contact structures 3 is surrounding the contact structure material from two directions, these edges are etched more rapidly than the centered portions of the top surfaces of the contact structures and the lower portions of the sidewalls thereof.

Preferably the etching step of FIG. 15 is performed by means of wet etching selectively along predetermined crystallographic orientations, thereby forming inclined surfaces 19 at the top portions 9 of the contact structures, which inclined surfaces 19 are planar facets 16 having a predetermined crystallographic orientation, like an orientation indicated by the group of Miller indices {110}.

Subsequent to shaping the contour of the contact structures by the additional etching step of FIG. 15, a dielectric material 21 (FIG. 16) is deposited and planarized, thereby filling spaces between the contact structures 3 and removing top regions 29 (FIG. 15) of upper portions 9 of the contact structures 3. By choosing the height in which planarization is stopped, the width d of the top surfaces 7 of the contact structures 3 is adjusted easily.

Subsequently a conductive material 25 is deposited on the top surfaces 7 of the contact structures 3 and on the top surfaces of the dielectric material 21 (FIG. 17) and the conductive material 25 is patterned as illustrated in FIG. 18 so as to obtain a plurality of bitlines 14 directly arranged on the top surfaces 7 of the contact structures 3. Though in FIGS. 15 to 18 horizontal lines are illustrated for identifying the lower portion 6 and the upper portion 9 of the respective contact structure 3, it is to be stated that, like in all other methods and embodiments, according to embodiments of the invention contact structures 3 are formed of one single, integrally formed structural element deposited by one single deposition step. Accordingly, in a real contact structure no interface surface separating the lower portions 6 from the upper portions 9 of the contact structures 3 is present.

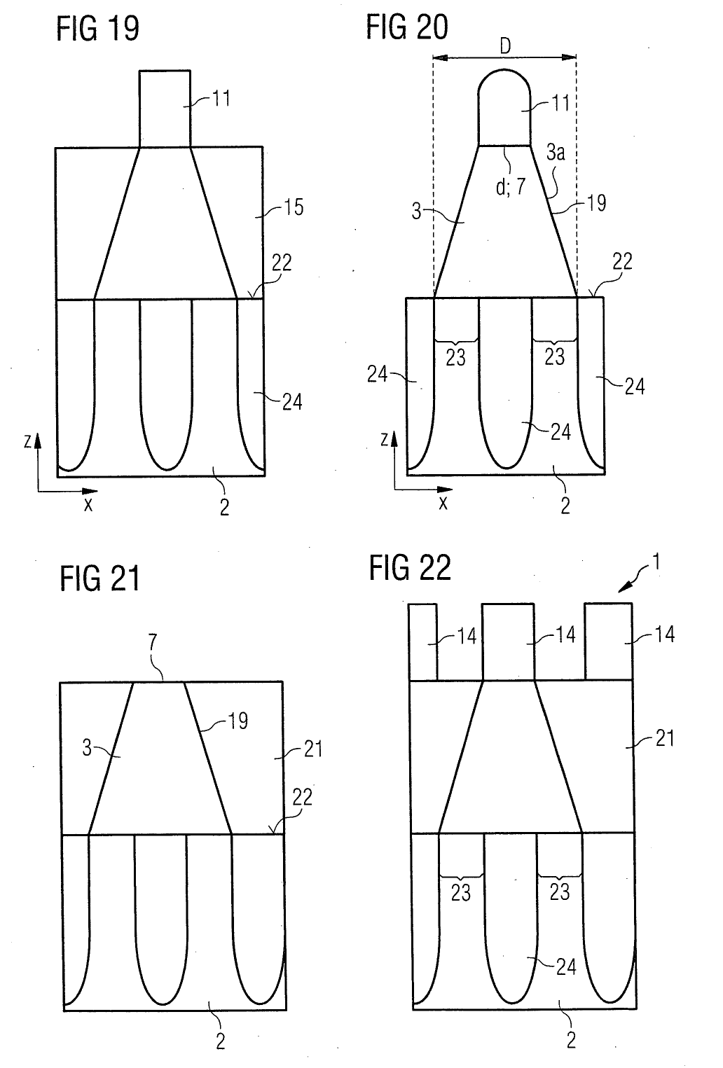

FIGS. 19 to 22 illustrate a fourth embodiment method according to the present invention.

The method starts with the steps illustrated in FIGS. 2 to 5 and then proceeds the depositing a conductive material 15 as illustrated in FIG. 6A. For patterning the conductive material 15, a mask 11 (FIG. 19) is deposited thereon and the conductive material 15 is etched through the mask 11 (FIG. 20) using an etching process that forms inclined sidewalls 19 so as to obtain trapezoidal contact structures 3 having a top surface 7 of a width d significantly smaller than the width D of the contact structures 3 along the first lateral direction x. The angle between the inclined sidewalls 19 and the normal direction z normal to the substrate surface 22 is at least 10°, preferably between 10° and 45° and more preferably between 15° and 25°. The etching process used for etching can be a dry etching process, like reactive ion etching. Appropriate angles of the inclined sidewalls may be achieved by adjusting the gas flows or the electrical power for forming the etching plasma.

Subsequently, the mask 11 is removed and spaces between the contact structures 3 are filled with dielectric material 21 (FIG. 21). Subsequently, a conductive material is deposited on the dielectric material 21 and on the top surfaces 7 of the dielectric structures and the conductive material is patterned so as to form bitlines 14 (FIG. 22) abutting to the top surfaces 7 of the contact structures 3. As in the first to third methods of the invention and their embodiments, the fourth method also serves to form an integrally formed contact structure 3 extending from the substrate surface 22 to the bitlines 14 and thereby removing the need to form any second contact structures like conventional contacts to interconnect. The thickness of the contact structures 3 in vertical direction z normal to the substrate surface 22 is approximately 300 to 350 nm, for instance.

In all of the previously described embodiment methods according to the invention the step of recessing the contact structures or etching the conductive material 15 for forming the contact structures 3 may be performed using potassium hydroxide, Cholin, TMAH (tetramethyl-ammonium-hydroxide) or EDP (ethylene-diamine-pyrocatecol), for instance. Of course, other substances may also be used therefor. In particular, in case of forming the contact structures of a monocrystalline semiconductor material, like doped monocrystalline silicon, the embodiments of the invention allow precise shaping of upper, tapered portions of the contact structures by exploiting selective etching with increased etching rates along predefined crystallographic orientations. By using any of the methods of the invention, conventional contacts to interconnect are rendered obsolete and the costs and efforts for forming semiconductor products like NROM (nitride read only memory) flash memories are reduced.

What is claimed is:

1. A method for forming a semiconductor product, the method comprising:
a) providing a semiconductor body having a surface;
b) forming wordlines above the semiconductor body, the wordlines extending along a first direction parallel to the semiconductor body surface and being provided at a distance from one another;
c) forming contact structures and first filling structures between the wordlines, the contact structures having a lateral width along the first direction and being separated along the first direction by the first filling structures;
d) forming a mask, the mask comprising mask openings extending along a second direction parallel to the surface, the second direction being different from the first direction;
e) wet etching portions of the contact structures through the mask openings, thereby reducing a width of upper portions of the contact structures along the first direction and forming recesses between the upper portions of the contact structures and the first filling structures;
f) filling the recesses with second filling structures; and
g) forming bitlines contacting the upper portions of the contact structures, the bitlines crossing over the contact structures along the second direction.

2. The method of claim 1, wherein in step d) the mask is formed to cover first portions of top surfaces of the contact structures and which comprises mask openings exposing second portions of the top surfaces of the contact structures.

3. The method of claim 1, wherein forming the contact structures includes expitaxially growing monocrystalline semiconductor material on the semiconductor body, between the wordlines, and wherein in step e) the monocrystalline semiconductor material is etched with an etching rate depending on crystallographic orientation of the local outer surface of the monocrystalline semiconductor material, thereby forming facets of predefined crystallographic orientations which confine the upper portions of the contact structures.

4. The method of claim 1, wherein step e) includes forming facets of predefined crystallographic orientation, thereby forming tapered upper portions of the contact structures, the tapered upper portions having top surfaces being smaller along the first direction than the width of the contact structures along the first direction.

5. The method of claim 4, wherein the contact structures are formed of monocrystalline silicon.

6. The method of claim 1, wherein step e) includes isotropically underetching the upper portions of the contact structures below the mask through the mask openings.

7. The method of claim 1, wherein step c) includes:
depositing a conductive material between the wordlines;
patterning the conductive material thereby forming the contact structures; and
filling spaces between the contact structures with dielectric material and planarizing the dielectric material, thereby forming the first filling structures.

8. The method of claim 1, wherein step c) includes:
depositing a dielectric material between the wordlines;
patterning the dielectric material thereby forming the first filling structures; and depositing a conductive material between the first filling structures and planarizing the conductive material, thereby forming the contact structures.

9. The method of claim 1, wherein the second filling structures are planarized between steps f) and g).

10. The method of claim 9, wherein top regions of tapered upper portions of the contact structures are removed when planarizing the second filling structures between steps f) and g).

11. The method of claim 1, wherein in step d) a mask is formed that covers centered first portions of top surfaces of the contact structures, the centered first portions being arranged in centered positions along the first direction, and wherein the mask comprises mask openings exposing second portions of the top surfaces of the contact structures, the second portions being arranged on opposed sides of the first portions along the first direction.

12. The method of claim 1, wherein in step d) a mask is formed that comprises mask openings being asymmetrically arranged on the top surfaces of the contact structures, for each respective contact structure one second portion of the top surface being exposed, the second portion being arranged at a de-centered position along the first direction.

13. The method of claim 1, wherein in steps e) and f) the contact structures are shaped such that top surfaces of the contact structures have a width that is smaller than a width of the contact structures along the first direction.

14. The method of claim 1, wherein step g) includes depositing a conductive material on top surfaces of the contact structures and patterning the conductive material thereby forming the bitlines.

15. A method of forming a semiconductor product (1), the method comprising:
a) providing a semiconductor body having a body surface;
b) forming wordlines above the semiconductor body, the wordlines extending along a first direction parallel to the body surface and being provided at a distance from one another;
c) forming contact structures between the wordlines, the contact structures having a width along the first direction and being separated along the first direction from one another by spaces;
d) wet etching the contact structures thereby forming tapered upper portions of the contact structures, the tapered upper portions each comprising top regions being smaller along the first direction, than the width of the contact structures along the first direction;
e) filling the spaces between the contact structures and covering the tapered upper portions of the contact structures with a dielectric material;
f) planarizing the dielectric material; and
g) forming bitlines contacting the top regions of the upper portions of the contact structures.

16. The method of claim 15, wherein the contact structures are formed of a monocrystalline semiconductor material epitaxially grown on the body surface in step c) and wherein in step d) the contact structures are etched with an etching rate depending on crystallographic orientation of the local outer surface of the monocrystalline semiconductor material, thereby forming facets of predefined crystallographic orientation and being inclined relative to the body surface, the facets confining the tapered upper portions of the contact structures.

17. The method of claim 16, wherein the contact structures are formed of monocrystalline silicon.

18. The method of claim 15, wherein in step d) tapered upper portions of the contact structures comprising centered top regions are formed, the centered top regions being arranged in centered positions along the first direction, and wherein step f) includes removing the centered top regions from the tapered upper portions.

19. The method of claim 15, wherein step f) includes exposing top surfaces of the tapered upper portions of the contact structures, the exposed top surfaces being parallel to the body surface and having a width, along the first direction, being smaller than the width of the contact structures along the first direction.

20. A method for forming a semiconductor product, the method comprising:
a) providing a semiconductor body having a body surface;
b) forming wordlines above the semiconductor body, the wordlines extending along a first direction parallel to the body surface and being provided at a distance from one another;
c) depositing a conductive material between the wordlines;
d) forming a mask on the wordlines and on the conductive material, the mask comprising mask openings extending along a second direction parallel to the body surface, the second direction being different from the first direction;
e) etching the conductive material through the mask openings, thereby forming contact structures having a width along the first direction and being separated from one another along the first direction by spaces, the contact structures having sidewalls being inclined relative to the body surface and further comprising upper portions that have a width, along the first direction, smaller than the width of the contact structures along the first direction;
f) filling the spaces between the contact structures with a dielectric material; and
g) forming bitlines contacting the upper portions of the contact structures, the bitlines crossing over the contact structures along the first direction.

21. The method of claim 20, wherein in step e) contact structures comprising sidewalls inclined by an angle of larger than 10° relative to the normal direction to the body surface are formed.

22. The method of claim 20, wherein in step e) contact structures comprising sidewalls inclined by an angle of between 10° and 45° relative to the normal direction to the body surface are formed.

23. The method of claim 22, wherein in step e) contact structures comprising sidewalls inclined by an angle of between 15° and 25° relative to the normal direction to the body surface are formed.

24. The method of claim 20, wherein the dielectric material is planarized between steps f) and g).

25. The method of claim 20, wherein step a) includes providing a semiconductor body comprising active areas formed line-shaped and extending along a second direction different from the first direction, the semiconductor body further comprising trenches arranged between the active areas and filled with trench isolation fillings, each trench isolation filling being formed line-shaped and isolating two respective areas from one another.

26. The method of claim 25, wherein contact structures each contacting two respective areas and passing across one respective trench isolation filling are formed.

27. The method of claim 25, wherein in step a) a semiconductor body is provided, which further comprises a charge-trapping layer sandwiched between a top oxide layer and a bottom oxide layer, the bottom oxide layer being disposed on the substrate surface.

28. The method of claim 27, wherein in step b) the wordlines are formed on the top oxide layer.

29. The method of claim 27, wherein the charge-trapping layer comprises a silicon nitride layer.

30. The method of claim 25, wherein contact structures are formed, which are arranged at a distance from one another along the first direction, which distance corresponds to the width of the trench isolation fillings along the first direction.

31. A semiconductor product comprising:
a semiconductor body having a body surface;
a plurality of wordlines arranged at a distance from one another and running along a first direction over the body surface;
a plurality of contact structures provided between the wordlines and a plurality of dielectric filling structures provided between the wordlines, the filling structures separating the contact structures from one another along the first direction, the contact structures contacting the substrate surface and comprising a top surface provided at a distance from the body surface, the contact structures further having a width along the first direction; and
a plurality of bitlines contacting the top surfaces of the contact structures;
wherein the contact structures each are formed of an integrally formed conductive structural element comprising inclined surfaces;
wherein the contact structures each comprise a lower portion and an upper portion;
wherein the top surface forms part of the upper portion of the respective contact structure; and
wherein the upper portions of the contact structures each comprise an inclined surface being inclined relative to the substrate surface and relative to the normal direction to the substrate surface, the top surface abutting to the inclined surfaces and having a width along the first direction being smaller than a width of the contact structure along the first direction.

32. The semiconductor product of claim 31, wherein the contact structures are formed of a monocrystalline semiconductor material and wherein the inclined surfaces are facets having a predefined crystallographic orientation.

33. The semiconductor product of claim 30, wherein the lower portions of the contact structures comprise sidewalls arranged at a distance from one another larger then the width of the top surface along the first direction.

34. The semiconductor product of claim 31, wherein the lower portions of the contact structures comprise sidewalls arranged at a distance from one another corresponding to the width of the contact structures along the first direction.

35. The semiconductor product of claim 31, wherein the top surfaces of the contact structures are arranged in a centered position, along the first direction, on the upper portions of the contact structures.

36. The semiconductor product of claim 35, wherein each contact structure comprises two respective inclined surfaces arranged on opposed sides of the top surface.

37. The semiconductor product of claim 31, wherein each contact structure comprises a tapered upper portion comprising at least one inclined surface and one top surface parallel to the substrate surface.

38. The semiconductor product of claim 31, wherein the sidewalls of the lower portions of the contact structures are abutting to first filling structures and wherein the inclined surfaces of the upper portions of the contact structures are abutting to second filling structures.

39. The semiconductor product of claim 31, wherein the width of the top surfaces of the contact structures along the first direction is less than half of the width of the contact structures along the first direction.

40. A semiconductor product comprising:
a semiconductor body having a body surface;
a plurality of wordlines arranged at a distance from one another and running along a first direction over the body surface;
a plurality of contact structures provided between the wordlines and a plurality of dielectric filling structures provided between the wordlines, the filling structures separating the contact structures from one another along the first direction, the contact structures contacting the body surface and comprising a top surface provided at a distance from the substrate surface, the contact structures further having a width along the first direction; and
a plurality of bitlines contacting the top surfaces of the contact structures;
wherein the contact structures each are formed of an integrally formed conductive structural element comprising inclined surfaces; and
wherein the contact structures comprise inclined surfaces extending from the body surface to the top surface of the contact structure, the inclined surfaces being inclined by an angle of larger than 10° relative to the normal direction to the body surface.

41. The semiconductor product of claim 40, wherein the inclined surfaces are inclined by an angle of between 10° and 45° relative to the normal direction to the substrate surface.

42. The semiconductor product of claim 40, wherein each contact structure comprises two inclined surfaces adjacent to the top surface and being arranged on opposed sides of the top surface.

43. The method of claim 40, wherein the width of the top surfaces of the contact structures along the first direction is less than two-thirds of the width of the contact structures along the first direction.

44. The semiconductor product of claim 40, wherein the semiconductor body comprises active areas, the active areas being formed line-shaped and extending along a second direction different from the first direction.

45. The semiconductor product of claim 44, wherein the semiconductor body comprises trenches arranged between the active areas and being filled with trench isolation fillings, each trench isolation filling being formed line-shaped and isolating two respective active areas from one another.

46. The semiconductor product of claim 45, wherein each contact structure contacts two respective active areas and passes across one respective trench isolation filling.

47. The semiconductor product of claim 45, wherein the semiconductor product comprises portions of a charge-trapping layer arranged between the active areas and the wordlines.

48. The semiconductor product of claim 47, wherein each portion of the charge-trapping layer is sandwiched between a bottom oxide layer and a top oxide layer.

49. The semiconductor product of claim 48, wherein the charge-trapping layer comprises silicon nitride layer.

50. The semiconductor product of claim 40, wherein the semiconductor product comprises a memory array comprising a plurality of non-volatile memory cells.
